(19) United States
(12) Patent Application Publication
(10) Pub. No.: US 2022/0181504 A1
(43) Pub. Date: Jun. 9, 2022

(54) SEMICONDUCTOR DEVICE AND PRODUCTION METHOD FOR SEMICONDUCTOR DEVICE

(71) Applicant: KYOCERA Corporation, Kyoto-shi, Kyoto (JP)

(72) Inventor: Tatsuro SAWADA, Tsukuba-shi (JP)

(73) Assignee: KYOCERA Corporation, Kyoto-shi, Kyoto (JP)

(21) Appl. No.: 17/599,040

(22) PCT Filed: Mar. 26, 2020
(86) PCT No.: PCT/JP2020/013716

§ 371 Date: Sep. 28, 2021

(30) Foreign Application Priority Data
Mar. 29, 2019 (JP) 2019-065368

(51) Int. Cl. H01L 29/872; H01L 29/66

(52) U.S. Cl. CPC H01L 29/8725; H01L 29/66212; H01L 29/7397; H01L 29/66348; H01L 29/66522; H01L 29/6606

(57) ABSTRACT

A semiconductor device includes: a semiconductor substrate; a first semiconductor layer of a first conductivity type thereon; a second semiconductor layer of a second conductivity type deposited using epitaxial growth on a bottom of the first semiconductor layer; a trench including a lateral surface constituted by the first semiconductor layer and a bottom surface at least partly constituted by the second semiconductor layer; an insulating film that covers the bottom surface and the lateral surface; a conductive body inside the trench; and a metal film electrically connected to the conductive body and forms a Schottky barrier with a surface of the first semiconductor layer. The second semiconductor layer constitutes all or a middle portion of the bottom surface and is within the trench in a plan view of the substrate.

### TECHNICAL FIELD

The present disclosure relates to a semiconductor device such as a diode and a transistor having a trench structure, and a production method for the semiconductor device.

### BACKGROUND ART

Conventionally, as described in JP 2016-502270A, there has been known a semiconductor device having a trench structure in which a trench is formed in a semiconductor layer having a first conductivity type that forms a Schottky barrier, and a lightly doped region of a second conductivity type is formed in the semiconductor layer disposed at the bottom of the trench.

### SUMMARY OF INVENTION

### Technical Problem

In the conventional semiconductor device described above, in a plan view of the semiconductor substrate, the low-concentration region of the second conductivity type protrudes out of the trench.

In such a structure where the low-concentration region of the second conductivity type protrudes outward from the bottom portion of the trench, the low-concentration region of the second conductivity type protrudes in a conductive region for forward current. This causes an increase in on-resistance and degradation of the forward characteristics.

By forming the above low-concentration region of the second conductivity type to improve the voltage resistance, and also by forming the region larger, the voltage resistance can be improved, but at the same time the on-resistance will increase. It is difficult to improve the voltage resistance while suppressing the increase in on-resistance.

Also, for certain semiconductor materials such as next-generation device materials (GaN, SiC, and the like), there may be a situation in which ion implantation technology is not yet fully established. When such materials are selected, it may be difficult to precisely form the low concentration region of the second conductivity type in the desired range using ion implantation techniques.

### Solution to Problem

According to one embodiment of the present disclosure, there is provided a semiconductor device including: a semiconductor substrate; a first semiconductor layer of a first conductivity type that is deposited on a surface of the semiconductor substrate; a second semiconductor layer of a second conductivity type that is deposited by crystal growth using epitaxial growth on a bottom of a recess of the first semiconductor layer; a trench that has a lateral surface constituted by the first semiconductor layer and a bottom surface at least partly constituted by the second semiconductor layer; an insulating film that covers the bottom surface and the lateral surface of the trench; a conductive body that fills inside the trench that is covered by the insulating film; and a metal film that is electrically connected to the conductive body and forms a Schottky barrier with a surface of the first semiconductor layer, wherein the second semiconductor layer constitutes all or a middle portion of the bottom surface of the trench and is within a region of the trench in a plan view of the semiconductor substrate.

According to one embodiment of the present disclosure, there is provided a production method for a semiconductor device, the semiconductor device including: a semiconductor substrate; a first semiconductor layer of a first conductivity type that is deposited on a surface of the semiconductor substrate; a second semiconductor layer of a second conductivity type that is deposited on a bottom of a recess of the first semiconductor layer; a trench that has a lateral surface constituted by the first semiconductor layer and a bottom surface at least partly constituted by the second semiconductor layer; an insulating film that covers the bottom surface and the lateral surface of the trench; a conductive body that fills inside the trench that is covered by the insulating film; and a metal film that is electrically connected to the conductive body and forms a Schottky barrier with a surface of the first semiconductor layer, the production method including: depositing the second semiconductor layer including an impurity of a second conductivity type by epitaxial growth on the first semiconductor layer.

### BRIEF DESCRIPTION OF DRAWINGS

FIG. 1 is a cross-sectional schematic diagram to illustrate a first embodiment of the present disclosure.

FIG. 2 is a cross-sectional schematic diagram to illustrate the first embodiment of the present disclosure.

FIG. 3 is a cross-sectional schematic diagram to illustrate the first embodiment of the present disclosure.

FIG. 4 is a cross-sectional schematic diagram to illustrate the first embodiment of the present disclosure.

FIG. 5 is a cross-sectional schematic diagram to illustrate the first embodiment of the present disclosure.

FIG. 6 is a cross-sectional schematic diagram to illustrate the first embodiment of the present disclosure.

FIG. 7 is a cross-sectional schematic diagram to illustrate the first embodiment of the present disclosure.

FIG. 8 is a cross-sectional schematic diagram to illustrate the first embodiment of the present disclosure.

FIG. 9 is a cross-sectional schematic diagram to illustrate a second embodiment of the present disclosure.

FIG. 10 is a cross-sectional schematic diagram to illustrate the second embodiment of the present disclosure.

FIG. 11 is a cross-sectional schematic diagram to illustrate the second embodiment of the present disclosure.

FIG. 12 is a cross-sectional schematic diagram to illustrate the second embodiment of the present disclosure.

FIG. 13 is a cross-sectional schematic diagram to illustrate the second embodiment of the present disclosure.

FIG. 14 is a cross-sectional schematic diagram to illustrate the second embodiment of the present disclosure.

FIG. 15 is a cross-sectional schematic diagram to illustrate the second embodiment of the present disclosure.

FIG. 16 is a cross-sectional schematic diagram to illustrate a third embodiment of the present disclosure.

FIG. 17 is a cross-sectional schematic diagram to illustrate the third embodiment of the present disclosure.

FIG. 18 is a cross-sectional schematic diagram to illustrate the third embodiment of the present disclosure.

FIG. 19 is a cross-sectional schematic diagram to illustrate the third embodiment of the present disclosure.

FIG. 20 is a cross-sectional schematic diagram to illustrate the third embodiment of the present disclosure.

FIG. 21 is a cross-sectional schematic diagram to illustrate the third embodiment of the present disclosure.

FIG. 22 is a cross-sectional schematic diagram to illustrate the third embodiment of the present disclosure.

FIG. 23 is a cross-sectional schematic diagram to illustrate the third embodiment of the present disclosure.

FIG. 24 is a cross-sectional schematic diagram to illustrate the third embodiment of the present disclosure.

FIG. 25 is a cross-sectional schematic diagram to illustrate a fourth embodiment of the present disclosure.

FIG. 26 is a cross-sectional schematic diagram to illustrate the fourth embodiment of the present disclosure.

FIG. 27 is a cross-sectional schematic diagram to illustrate the fourth embodiment of the present disclosure.

FIG. 28 is a cross-sectional schematic diagram to illustrate the fourth embodiment of the present disclosure.

FIG. 29 is a cross-sectional schematic diagram to illustrate the fourth embodiment of the present disclosure.

FIG. 30 is a cross-sectional schematic diagram to illustrate the fourth embodiment of the present disclosure.

FIG. 31 is a cross-sectional schematic diagram to illustrate a fifth embodiment of the present disclosure.

FIG. 32 is a cross-sectional schematic diagram to illustrate the fifth embodiment of the present disclosure.

FIG. 33 is a cross-sectional schematic diagram to illustrate the fifth embodiment of the present disclosure.

FIG. 34 is a cross-sectional schematic diagram to illustrate the fifth embodiment of the present disclosure.

FIG. 35 is a cross-sectional schematic diagram to illustrate the fifth embodiment of the present disclosure.

FIG. 36 is a cross-sectional schematic diagram to illustrate the fifth embodiment of the present disclosure.

FIG. 37 is a cross-sectional schematic diagram to illustrate the fifth embodiment of the present disclosure.

FIG. 38 is a cross-sectional schematic diagram to illustrate the fifth embodiment of the present disclosure.

FIG. 39 is a cross-sectional schematic diagram to illustrate the fifth embodiment of the present disclosure.

FIG. 40 is a cross-sectional schematic diagram to illustrate the fifth embodiment of the present disclosure.

FIG. 41 is a cross-sectional schematic diagram to illustrate a sixth embodiment of the present disclosure.

FIG. 42 is a graph comparing examples of comparison and the present invention regarding a forward voltage and a voltage resistance.

### DESCRIPTION OF EMBODIMENTS

Hereinafter, an embodiment of the present disclosure will be explained with reference to the drawings.

### First Embodiment

First, a production method for a semiconductor device according to a first embodiment and the semiconductor device will be described.

### (Production Method)

The semiconductor device is produced as follows.

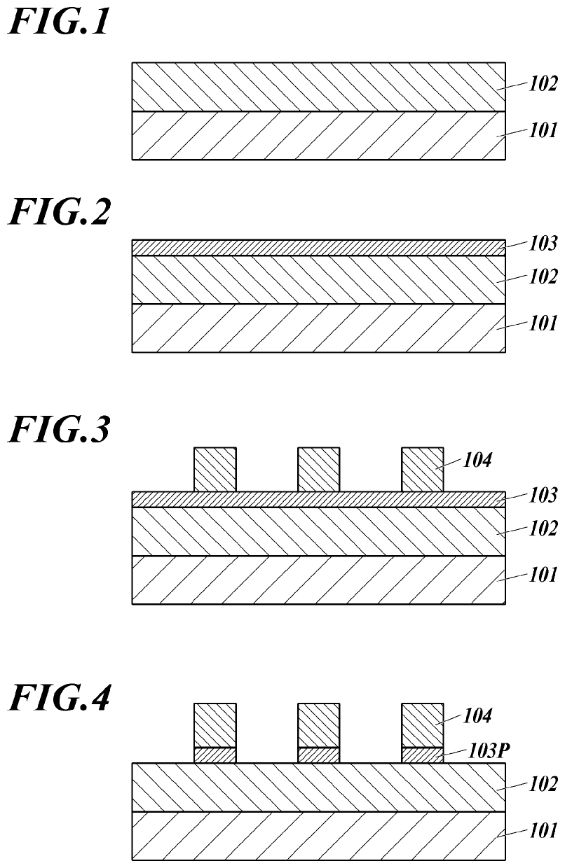

FIG. 1 shows a configuration in which a lower layer portion 102 of a first semiconductor layer is deposited on a semiconductor substrate 101. As shown in FIG. 2, in a second semiconductor layer depositing process on the configuration, a second semiconductor layer 103 including an impurity of a second conductivity type (P-type) is deposited by epitaxial growth.

The semiconductor substrate 101 is an N-type high-concentration silicon substrate. The semiconductor layer 102 is an N-type low-concentration semiconductor layer deposited on the surface of the semiconductor substrate 101 by an epitaxial growth method.

Next, as shown in FIG. 3, an etching mask pattern 104 is formed on the second semiconductor layer 103.

Next, as shown in FIG. 4, the second semiconductor layer 103 that is exposed from the etching pattern 104 is removed by etching using the etching mask pattern 104 as a mask, so that the second semiconductor layer 103P under the etching pattern 104 remains. As described above, after the second semiconductor layer depositing process, a portion remains after selective etching of the semiconductor layer formed in the second semiconductor layer depositing process and is referred to as the second semiconductor layer 103P of the product.

Next, as shown in FIG. 5, an upper layer portion 105 of the N-type first semiconductor layer is deposited adjoining the perimeter of the second semiconductor layer 103P, so as to be thicker than the second semiconductor layer 103P to form a trench 106.

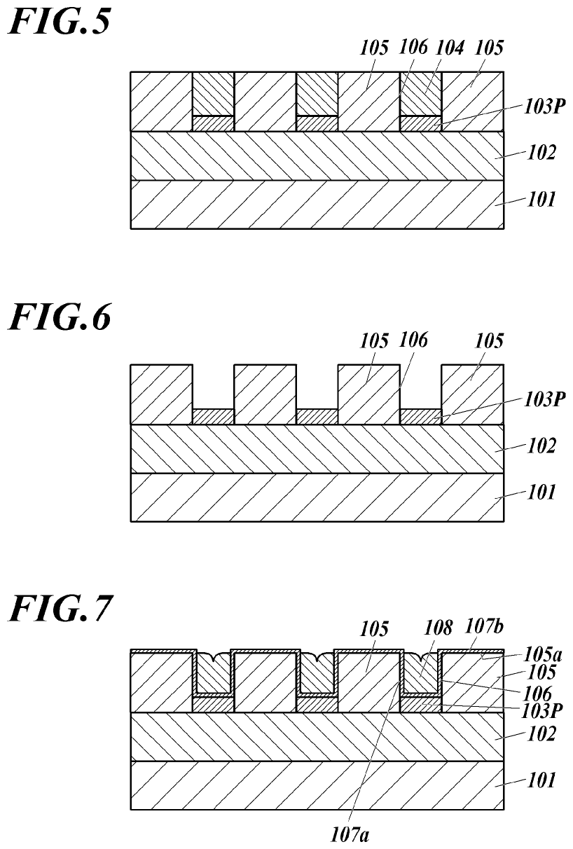

Next, as shown in FIG. 6, the etching mask pattern 104 is removed. Then, a trench 106 appears. Any number of trenches 106 can be formed.

Next, insulating films (thermal oxide films) 107a and 107b are formed on the surface of the upper layer portion 105 including inside the trench 106 and an upper surface of the second semiconductor layer 103P exposed at a bottom surface of the trench 106 as shown in FIG. 7, and then the trench 106 filled with a conductive body 108. As the material of the conductive body 108, polysilicon or a metal material is applied.

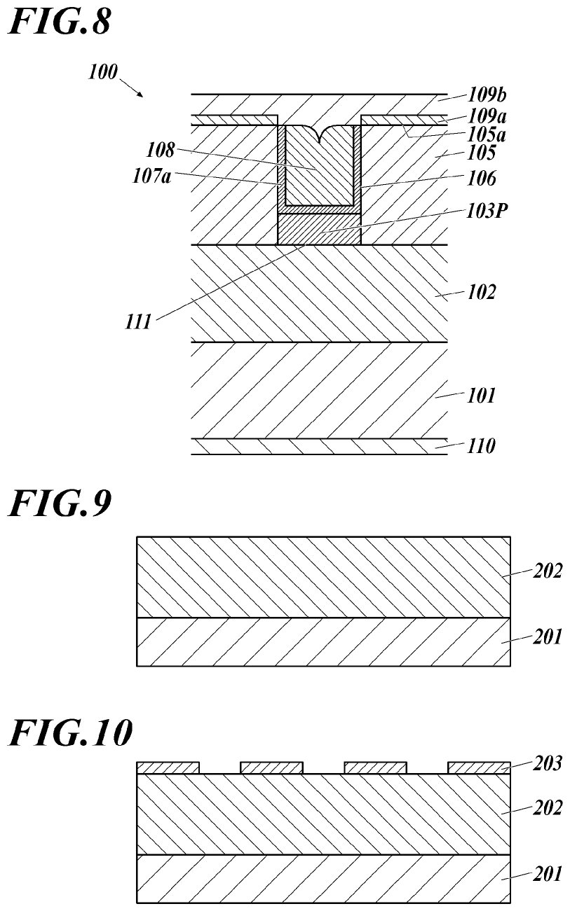

Furthermore, after the insulating film 107b around the trench 106 is removed, as shown in FIG. 8, a Schottky metal film 109a is joined with the upper surface 105a of the upper layer portion 105 to form a Schottky barrier, and then a surface electrode metal film 109b is further formed to connect the Schottky metal film 109a and the conductive body 108. Furthermore, a back electrode metal film 110 is formed.

### (Semiconductor Device)

The semiconductor device 100 shown in FIG. 8 that can be produced by the above production method, for example, includes: the semiconductor substrate 101 that has a first conductivity type at a relatively high concentration; the first semiconductor layers 102, 105 that are deposited on the surface of the semiconductor substrate 101 and have the first conductivity type at a relatively low concentration; the second semiconductor layer 103P of the second conductivity type deposited on a bottom of a recess 111 of the first semiconductor layers 102, 105 by crystal growth using epitaxial growth; the trench 106 having a lateral surface constituted by the upper layer portion 105 of the first semiconductor layer and a bottom surface entirely constituted by the second semiconductor layer 103P; the insulating film 107a that covers the bottom surface and the lateral surface of the trench 106; the conductive body 108 that fills the inside of the trench 106 covered by the insulating film 107a; and the Schottky metal film 109a that electrically connects to the conductive body 108 and forms a Schottky barrier with the upper surface 105a of the upper layer portion 105 of the first semiconductor layer.

The second semiconductor layer 103P is arranged under the trench 106 and is within the region of the trench 106 in a plan view of the semiconductor substrate 101.

The region in the semiconductor layer deposited on the semiconductor substrate 101 except the region of the trench 106 in the plan view of the semiconductor substrate 101 is occupied by the first conductive type (N-type) region. Therefore, it is possible to ensure a large conductive region for forward current under a Schottky junction.

The semiconductor device 100 can be applied to SBDs (Schottky diodes), MOSFETs (metal-oxide-semiconductor field-effect transistors), IGBTs (Insulated Gate Bipolar Transistors), and the like.

When the semiconductor device 100 constitutes a MOSFET, the P-body, gate, and the like are formed in the center portion, and the surface electrode metal film 109b serves as a source electrode and the back electrode metal film 110 serves as a drain electrode. When the semiconductor device 100 constitutes an IGBT, further, a p-type high-concentration substrate is applied as the semiconductor substrate 101, the surface electrode metal film 109b serves as an emitter electrode, and the back electrode metal film 110 serves as a collector electrode.

### Second Embodiment

Next, a production method for a semiconductor device according to a second embodiment and the semiconductor device will be described.

### (Production Method)

The semiconductor device is produced as follows.

FIG. 9 shows a configuration in which a first semiconductor layer 202 is deposited on a semiconductor substrate 201. As shown in FIG. 10, an etching mask pattern 203 is formed on the first semiconductor layer 202. The semiconductor substrate 201 is an N-type high-concentration silicon substrate. The semiconductor layer 202 is an N-type low-concentration semiconductor layer deposited on the surface of the semiconductor substrate 201 by the epitaxial growth method.

Next, as shown in FIG. 11, a recess 204 is formed in the first semiconductor layer 202 by etching using the etching mask pattern 203 as a mask.

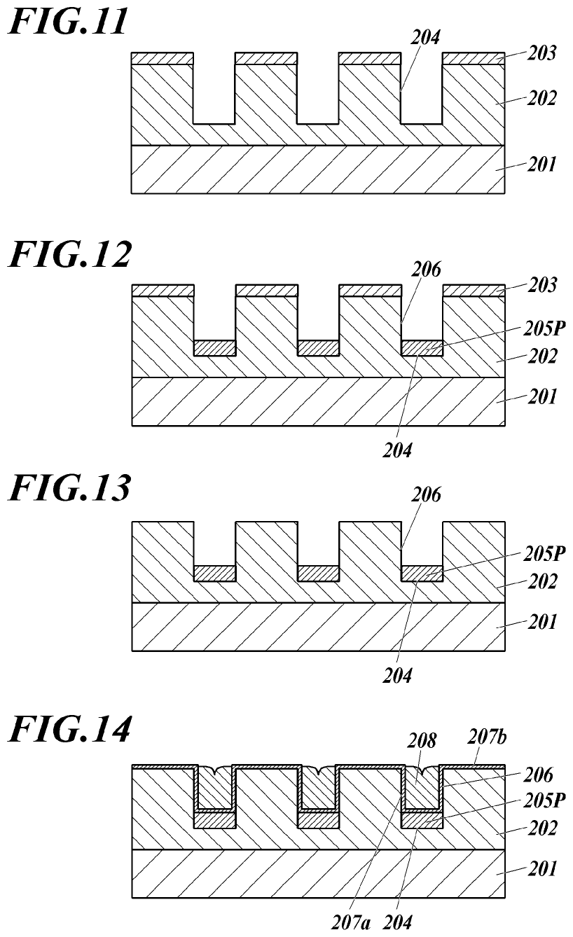

Next, as shown in FIG. 12, in a second semiconductor layer depositing process, a second semiconductor layer 205P including an impurity of a second conductivity type (P-type) is deposited on the bottom of the recess 204 by epitaxial growth. A trench 206 is thus formed with the upper surface of the second semiconductor layer 205P as a bottom surface.

Next, as shown in FIG. 13, the etching mask pattern 203 is removed.

Next, insulating films (thermal oxide films) 207a and 207b are formed on the surface of the first semiconductor layer 202 including inside the trench 206 and an upper surface of the second semiconductor layer 205P exposed at a bottom surface of the trench 206 as shown in FIG. 14, and then the trench 206 is filled with a conductive body 208. As the material of the conductive body 208, polysilicon or a metal material is applied.

Furthermore, after the insulating film 207b around the trench 206 is removed, as shown in FIG. 15, a Schottky metal film 209a is joined with a surface 202a of the first semiconductor layer 202 to form a Schottky barrier, and then a surface electrode metal film 209b is further formed to connect the Schottky metal film 209a and the conductive body 208. Furthermore, a back electrode metal film 210 is formed.

### (Semiconductor Device)

The semiconductor device 200 shown in FIG. 15 that can be produced by the above production method, for example, includes: the semiconductor substrate 201 that has a first conductivity type at a relatively high concentration; the first semiconductor layer 202 that is deposited on the surface of the semiconductor substrate 201 and has the first conductivity type at a relatively low concentration; the second semiconductor layer 205P of the second conductivity type deposited on a bottom of the recess 204 of the first semiconductor layer 202 by crystal growth using epitaxial growth; the trench 206 having a lateral surface constituted by the upper layer portion 105 of the first semiconductor layer and a bottom surface entirely constituted by the second semiconductor layer 205P; the insulating film 207a that covers the bottom surface and the lateral surface of the trench 206; the conductive body 208 that fills the inside of the trench 206 covered by the insulating film 207a; and the Schottky metal film 209a that electrically connects to the conductive body 208 and forms a Schottky barrier with the surface 202a of the first semiconductor layer 202.

The second conductive type region 205P is arranged under the trench 206 and is within the region of the trench 206 in a plan view of the semiconductor substrate 201.

The region in the semiconductor layer deposited on the semiconductor substrate 201 except the region of the trench 206 in the plan view of the semiconductor substrate 201 is occupied by the first conductive type (N-type) region. Therefore, it is possible to ensure a large conductive region for forward current under a Schottky junction.

The semiconductor device 200 can be applied to SBDs (Schottky diodes), MOSFETs (metal-oxide-semiconductor field-effect transistors), IGBTs (Insulated Gate Bipolar Transistors), and the like.

When the semiconductor device 200 constitutes a MOSFET, the P-body, gate, and the like are formed in the center portion, and the surface electrode metal film 209b serves as a source electrode and the back electrode metal film 210 serves as a drain electrode. When the semiconductor device 200 constitutes an IGBT, further, a p-type high-concentration substrate is applied as the semiconductor substrate 201, the surface electrode metal film 209b serves as an emitter electrode, and the back electrode metal film 210 serves as a collector electrode.

### Third Embodiment

Next, a production method for a semiconductor device according to a third embodiment and the semiconductor device will be described.

### (Production Method)

The semiconductor device is produced as follows.

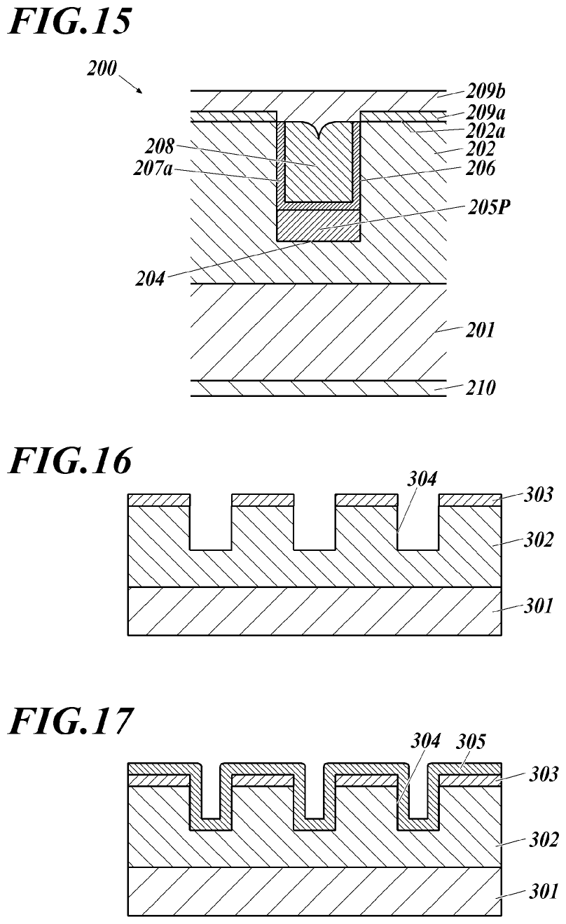

As shown in FIG. 16, in the same way as the above second embodiment, an insulator mask pattern 303 is formed on a first semiconductor layer 302 on a semiconductor substrate 301 and is open at a region where a trench is to be formed. A recess 304 is formed in the first semiconductor layer 302 by etching using the insulator mask pattern 303 as a mask (process of forming a recess).

Next, as a process of forming a mask after the process of forming a recess, first, an insulator layer 305 is formed as shown in FIG. 17. The insulator layer 305 is deposited on the insulator mask pattern 303 described in the above process of forming a trench. At the same time, the insulator layer 305 covers the bottom surface and the lateral surface of the recess 304. An insulating material that constitutes the insulator mask pattern 303 and the insulator layer 305 includes silicon oxide, silicon nitride, TEOS (tetraethyl orthosilicate), or the like. The insulator layer 205 is deposited using, for example, chemical vapor deposition (CVD).

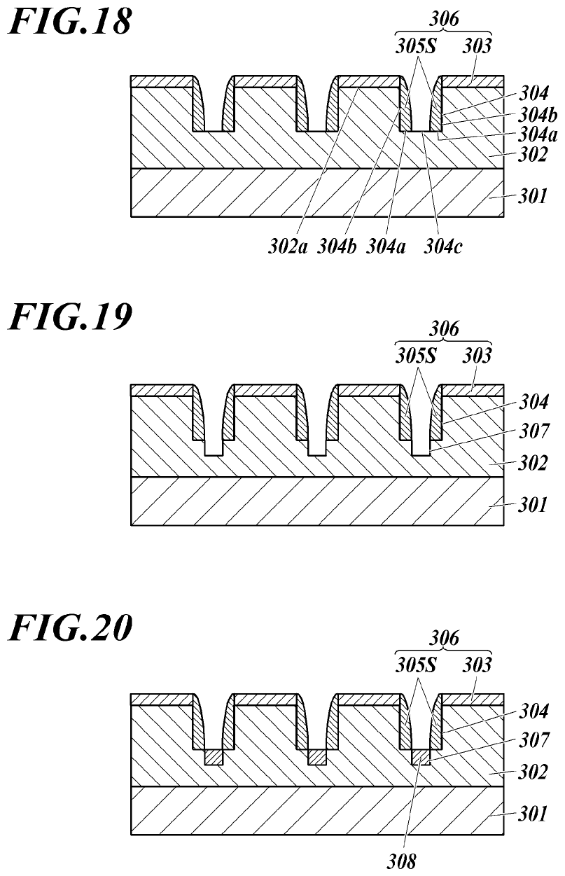

Next, as shown in FIG. 18, the entire surface is etched. The etching applied is anisotropic etching. As the anisotropic etching, a reactive etching method is applied in which the etching rate in the vertical direction, perpendicular to the surface, is larger than the etching rate in the horizontal direction, parallel to the surface.

Therefore, as shown in FIG. 18, it is possible to expose a middle portion 304c of the bottom surface of the recess 304 while a sidewall insulator 305S remains, which is a part of the insulator layer 305 and adheres to an outer edge portion 304a of the bottom surface and the lateral surface 304b of the recess 304. This is because the sidewall insulator 305S remains when the insulator on the middle portion 304c of the bottom surface of the recess 304 is removed by vertical etching.

The sidewall insulator 305S is thicker at the portion closer to the bottom surface of the recess 304 because the etching progresses more at the portion closer to the opening of the recess 304.

On the surface 302a of the first semiconductor layer 302 around the recess 304, the insulator mask pattern 303 is covered by the insulator layer 305 before etching as shown in FIG. 17. Therefore, when the insulator on the middle portion 304c of the bottom surface of the recess 304 is removed by vertical etching, the insulator mask pattern 303 also remains.

The insulator mask pattern 303 and the sidewall insulator 305S remaining after the above anisotropic etching are collectively referred to as an insulator mask pattern 306.

As shown in FIG. 18, the insulator mask pattern 306 covers the surface 302a of the first semiconductor layer 302 around the recess 304, the outer edge portion 304a of the bottom surface of the recess 304, and the lateral surface 304b of the recess 304, and is a pattern that exposes the middle portion 304c of the same bottom surface. This insulator mask pattern 306 is used as a mask for a subsequent process of depositing the second semiconductor layer.

Next, the process of depositing the second semiconductor layer is performed. In the process of depositing the second semiconductor layer, a second semiconductor layer 308 including an impurity of a second conductivity type is deposited on the first semiconductor layer 302 by epitaxial growth.

In this embodiment, using the insulator mask pattern 306 as a mask, the second semiconductor layer is deposited on the first semiconductor layer 302 exposed at the middle portion 304c of the bottom surface of the recess 304. However, prior to this process, a process of forming a small recess is performed.

As the process of forming a small recess, by etching of the first semiconductor layer 302 exposed at the middle portion 304c of the bottom surface of the recess 304 using the insulator mask pattern 306 as a mask as shown in FIG. 19, a small recess 307 in the first semiconductor layer 302 is formed at the middle portion 304c of the bottom surface of the recess 304.

Next, using the insulator mask pattern 306 as a mask as shown in FIG. 20, the second semiconductor layer 308 is deposited on the first semiconductor layer 302 exposed at the middle portion of the bottom surface of the recess 304. Here, since the small recess 307 has been formed in advance, the second semiconductor layer 308 is deposited in the small recess 307 using the insulator mask pattern 306 as a mask.

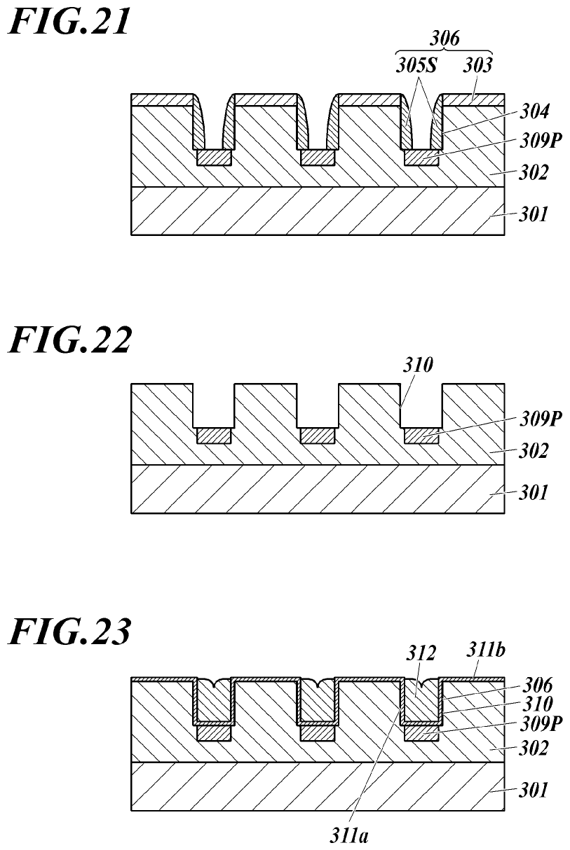

Next, the impurity in the second semiconductor layer 308 is diffused by heat treatment, and the second conductive type region 309P is formed as shown in FIG. 21.

The insulator mask pattern 306 is removed, and a trench 310 is formed with the upper surface of the second conductive type region 309P as the middle portion of the bottom surface.

Next, insulating films (thermal oxide films) 311a and 311b are formed on the surface of the first semiconductor layer 302 including inside the trench 310 and an upper surface of the second semiconductor layer 308 exposed at a bottom surface of the trench 306 as shown in FIG. 23, and then the trench 310 is filled with a conductive body 312. As the material of the conductive body 312, polysilicon or a metal material is applied.

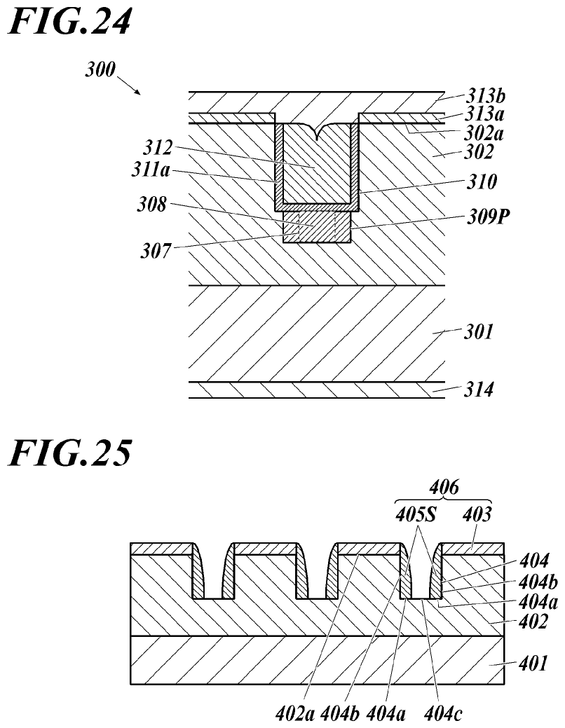

Furthermore, after the insulating film 311b around the trench 310 is removed, as shown in FIG. 24, a Schottky metal film 313a is joined with the surface 302a of the first semiconductor layer 302 to form a Schottky barrier, and then a surface electrode metal film 313b is further formed to connect the Schottky metal film 313a and the conductive body 312. Furthermore, a back electrode metal film 314 is formed.

### (Semiconductor Device)

The semiconductor device 300 shown in FIG. 24 that can be produced by the above production method, for example, includes: the semiconductor substrate 301 that has a first conductivity type at a relatively high concentration; the first semiconductor layer 302 that is deposited on the surface of the semiconductor substrate 301 and has the first conductivity type at a relatively low concentration; the second semiconductor layer 308 of the second conductivity type deposited on a bottom of the recess 304+307 of the first semiconductor layer 302 by crystal growth using epitaxial growth; the trench 310 having a lateral surface constituted by the first semiconductor layer 302 and a bottom surface whose middle portion is constituted by the second semiconductor layer 308; the insulating film 311a that covers the bottom surface and the lateral surface of the trench 310; the conductive body 312 that fills the inside of the trench 310 covered by the insulating film 311a; and the Schottky metal film 313a that electrically connects to the conductive body 312 and forms a Schottky barrier with the surface 302a of the first semiconductor layer 302.

The second semiconductor layer 308 and the second conductive type region 309P, using the second semiconductor layer 308 as a diffusion source of the second conductive type impurity, are arranged under the trench 310 and are within the region of the trench 206 in a plan view of the semiconductor substrate 201.

The second semiconductor layer 308 and the second conductive type region 309P constitute the middle portion of the bottom surface of the trench 310, and are within the region of the trench 310 without being in contact with the outer edge of the region of the trench 310 in a plan view of the semiconductor substrate 301. The first semiconductor layer 302 constitutes an outer edge portion of the bottom surface of the trench 310 excluding the middle portion.

The region in the semiconductor layer deposited on the semiconductor substrate 301 except the region of the trench 310 in the plan view of the semiconductor substrate 301 is occupied by the first conductive type (N-type) region. Therefore, it is possible to ensure a large conductive region for forward current under a Schottky junction.

In this embodiment, the bottom surface of the trench 310 is formed to be flat, that is, the outer edge portion constituted by the first semiconductor layer 302 and the middle portion constituted by the second semiconductor layer 308 are located at the same depth.

The semiconductor device 300 can be applied to SBDs (Schottky diodes), MOSFETs (metal-oxide-semiconductor field-effect transistors), IGBTs (Insulated Gate Bipolar Transistors), and the like.

When the semiconductor device 300 constitutes a MOSFET, the P-body, gate, and the like are formed in the center portion, and the surface electrode metal film 313b serves as a source electrode and the back electrode metal film 314 serves as a drain electrode. When the semiconductor device 300 constitutes an IGBT, further, a p-type high-concentration substrate is applied as the semiconductor substrate 301, the surface electrode metal film 313b serves as an emitter electrode, and the back electrode metal film 314 serves as a collector electrode.

### Fourth Embodiment

Next, a production method for a semiconductor device according to a fourth embodiment and the semiconductor device will be described.

### (Production Method)

The semiconductor device is produced as follows.

In the same manner as the process up to FIG. 18 of the above third embodiment, as shown in FIG. 25, a recess 404 is formed in the first semiconductor layer 402, and a sidewall insulator 405S is formed in the recess 404.

An insulator mask pattern 403 and the sidewall insulator 405S remaining after the anisotropic etching in the same manner as the above third embodiment are collectively referred to as an insulator mask pattern 406.

As shown in FIG. 25, the insulator mask pattern 406 covers the surface 402a of the first semiconductor layer 402 around the recess 404, an outer edge portion 404a of the bottom surface of the recess 404, and the lateral surface 404b of the recess 404, and is a pattern that exposes a middle portion 404c of the same bottom surface. This insulator mask pattern 406 is used as a mask for a subsequent process of depositing the second semiconductor layer.

Next, the process of depositing the second semiconductor layer is performed. In the process of depositing the second semiconductor layer, a second semiconductor layer 407P including an impurity of a second conductivity type is deposited on the first semiconductor layer 402 by epitaxial growth.

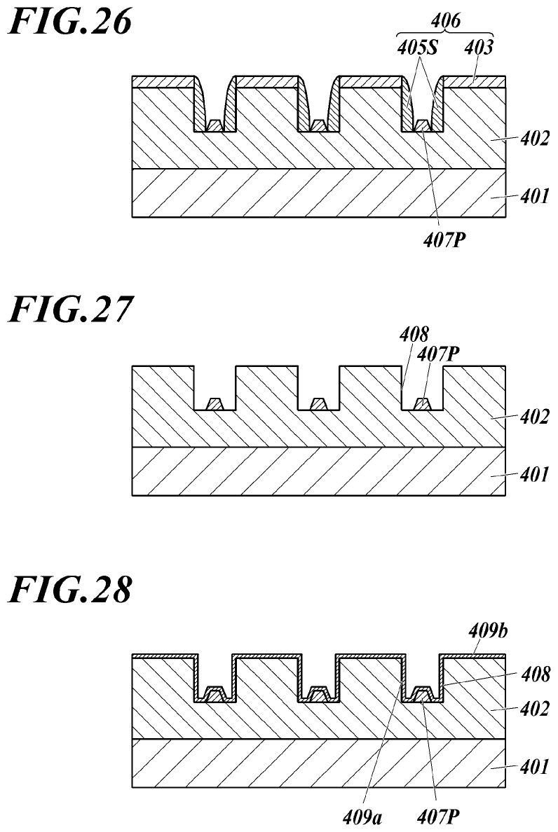

In this embodiment, using the insulator mask pattern 406 as a mask, the second semiconductor layer 407P is deposited on the first semiconductor layer 402 exposed at the middle portion 404c of the bottom surface of the recess 404 to obtain a structure shown in FIG. 26.

Next, the insulator mask pattern 406 is removed as shown in FIG. 27, and a trench 408 is formed with the upper surface of the second semiconductor layer 407P as a protruding middle portion of the bottom surface.

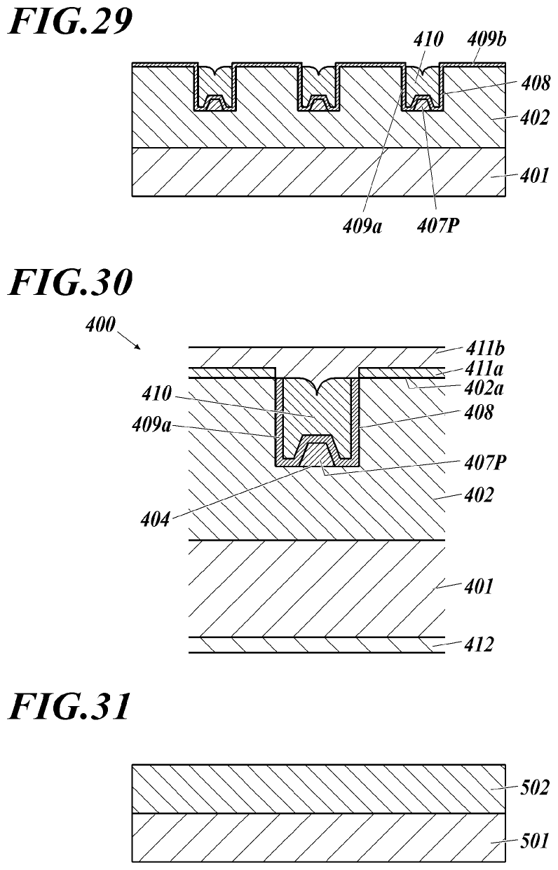

Next, insulating films (thermal oxide films) 409a and 409b are formed on the surface of the first semiconductor layer 402 including inside the trench 408 and an upper surface of the second semiconductor layer 407P exposed at a bottom surface of the trench 408 as shown in FIG. 28, and then the trench 408 is filled with a conductive body 410 as shown in FIG. 29. As the material of the conductive body 410, polysilicon or a metal material is applied.

Furthermore, after the insulating film 409b around the trench 408 is removed, as shown in FIG. 30, a Schottky metal film 411a is joined with the surface 402a of the first semiconductor layer 402 to form a Schottky barrier, and then a surface electrode metal film 411b is further formed to connect the Schottky metal film 411a and the conductive body 410. Furthermore, a back electrode metal film 412 is formed.

### (Semiconductor Device)

The semiconductor device 400 shown in FIG. 30 that can be produced by the above production method, for example, includes: the semiconductor substrate 401 that has a first conductivity type at a relatively high concentration; the first semiconductor layer 402 that is deposited on the surface of the semiconductor substrate 401 and has the first conductivity type at a relatively low concentration; the second semiconductor layer 407P of the second conductivity type deposited on a bottom of the recess 404 of the first semiconductor layer 402 by crystal growth using epitaxial growth; the trench 408 having a lateral surface constituted by the first semiconductor layer 402 and a bottom surface whose middle portion is constituted by the second semiconductor layer 407P; the insulating film 409a that covers the bottom surface and the lateral surface of the trench 408; the conductive body 410 that fills the inside of the trench 408 covered by the insulating film 409a; and the Schottky metal film 411a that electrically connects to the conductive body 410 and forms a Schottky barrier with the surface 402a of the first semiconductor layer 402.

The second semiconductor layer 407P is arranged under the trench 408 and is within the region of the trench 408 in a plan view of the semiconductor substrate 401.

The second semiconductor layer 408P constitutes the middle portion of the bottom surface of the trench 408, and is within the region of the trench 408 without being in contact with the outer edge of the region of the trench 408 in a plan view of the semiconductor substrate 401. The first semiconductor layer 402 constitutes an outer edge portion of the bottom surface of the trench 408 excluding the middle portion.

The region in the semiconductor layer deposited on the semiconductor substrate 401 except the region of the trench 408 in the plan view of the semiconductor substrate 401 is occupied by the first conductive type (N-type) region. Therefore, it is possible to ensure a large conductive region for forward current under a Schottky junction.

In this embodiment, the trench 408 has a protruding portion constituted by the second semiconductor layer 407P on the bottom surface, that is, the middle portion constituted by the second semiconductor layer 407P is formed so as to protrude with respect to the outer edge portion constituted by the first semiconductor layer 402.

The semiconductor device 400 can be applied to SBDs (Schottky diodes), MOSFETs (metal-oxide-semiconductor field-effect transistors), IGBTs (Insulated Gate Bipolar Transistors), and the like.

When the semiconductor device 400 constitutes a MOSFET, the P-body, gate, and the like are formed in the center portion, and the surface electrode metal film 411b serves as a source electrode and the back electrode metal film 412 serves as a drain electrode. When the semiconductor device 400 constitutes an IGBT, further, a p-type high-concentration substrate is applied as the semiconductor substrate 401, the surface electrode metal film 411b serves as an emitter electrode, and the back electrode metal film 412 serves as a collector electrode.

### Fifth Embodiment

Next, a production method for a semiconductor device according to a fifth embodiment and the semiconductor device will be described.

### (Production Method)

The semiconductor device is produced as follows.

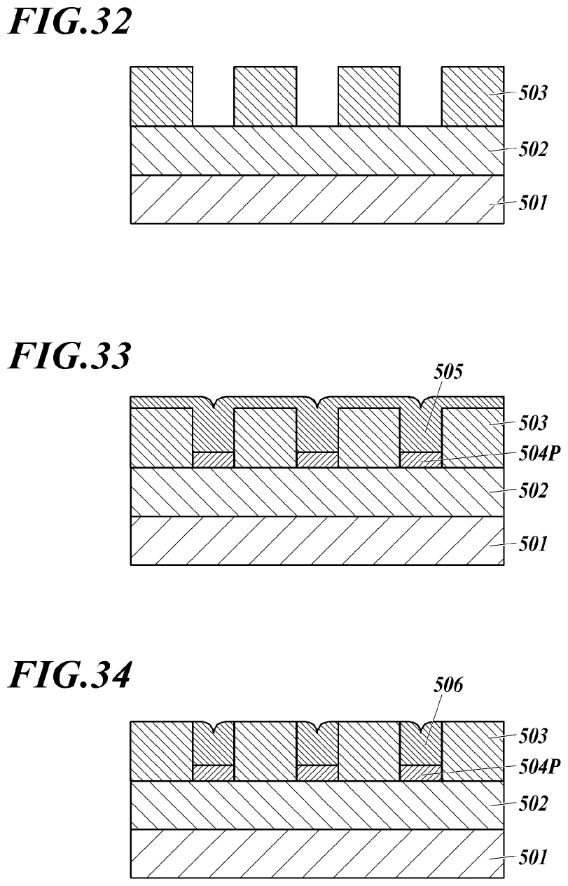

FIG. 31 shows a semiconductor substrate 501 and a lower layer portion 502 of a first semiconductor layer deposited thereon. On the surface of the lower layer portion 502, a mask pattern 503 that is open at a region where a trench is to be formed as shown in FIG. 32. The semiconductor substrate 501 is an N-type high-concentration silicon substrate. The lower layer portion 502 of a first semiconductor layer is an N-type low-concentration semiconductor layer deposited on the surface of the semiconductor substrate 501 by the epitaxial growth method.

Next, in a process of depositing the second semiconductor layer, a second semiconductor layer 504P including an impurity of a second conductivity type (P-type) is deposited on the bottom by epitaxial growth.

In the process of depositing the second semiconductor layer of this embodiment, on the lower layer portion 502 in the region where a trench is to be formed using the mask pattern 503 as a mask, the second semiconductor layer 504P is deposited so as to be thinner than the mask pattern 503. The resulting gap, that is, the gap formed by the second semiconductor layer 504P and the mask pattern 503, is filled with a nitride film 505 to obtain a structure shown in FIG. 33.

Next, as shown in FIG. 34, etching of the nitride film 505 is performed such that the mask pattern 503 is exposed, while a nitride film 506 remains in the opening of the mask pattern 503 on the second semiconductor layer 504P.

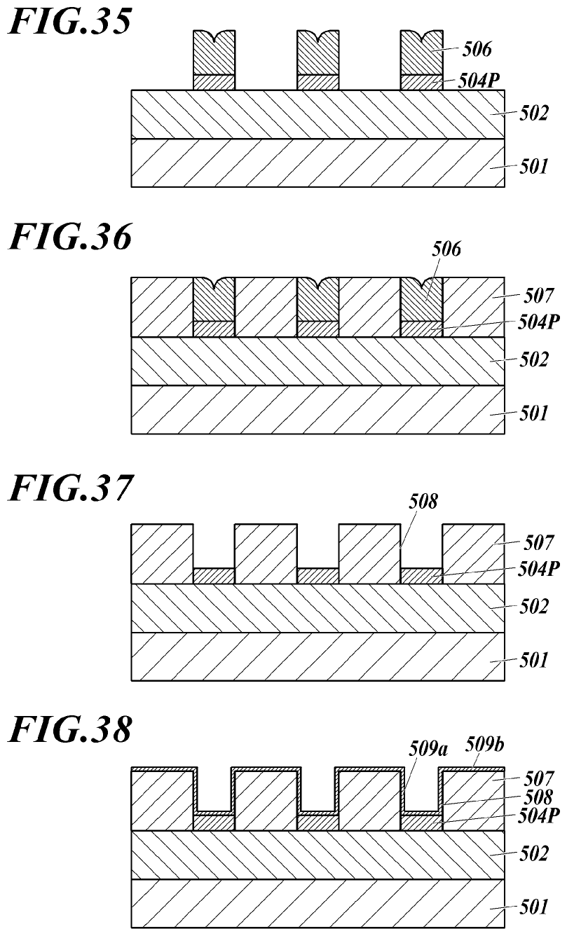

Next, the mask pattern 503 is removed as shown in FIG. 35, and an upper layer portion 507 of the first semiconductor layer that is thicker than the second semiconductor layer 504P is deposited on the lower layer portion 502 from which the mask pattern 503 is removed as shown in FIG. 36. The upper layer portion 507 is an N-type low-concentration semiconductor layer similar to the lower layer portion 502. The upper layer portion 507 is deposited on the surface of the lower layer portion 502 by epitaxial growth method using the nitride film 506 as a mask.

Next, as shown in FIG. 37, the nitride film 506 is removed, and the trench 508 is formed.

Next, as shown in FIG. 38, insulating films (thermal oxide films) 509a, 509b are formed on the surface of the upper layer portion 507 including inside the trench 508 and an upper surface of the second semiconductor layer 504P exposed at a bottom surface of the trench 508.

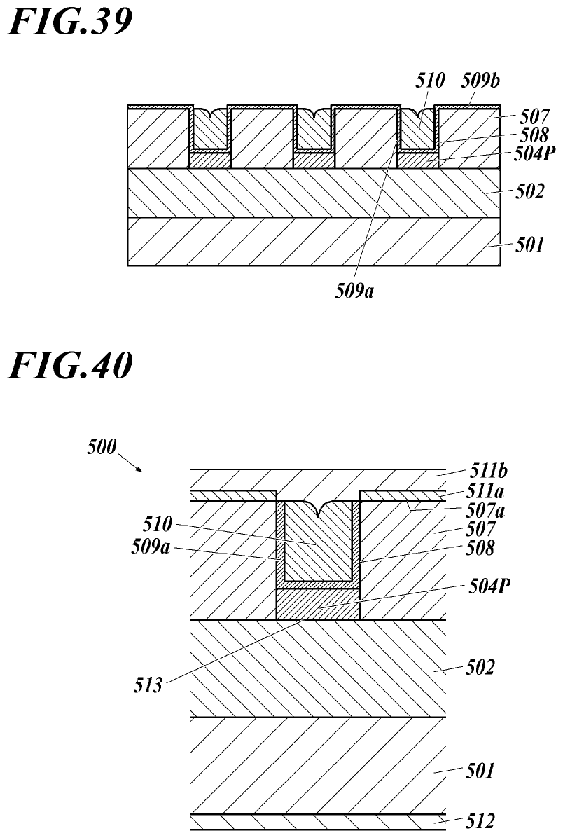

After that, the trench 508 is filled with a conductive body 510 as shown in FIG. 39. As the material of the conductive body 510, polysilicon or a metal material is applied.

Furthermore, after the insulating film 509b around the trench 508 is removed, as shown in FIG. 40, a Schottky metal film 511a is joined with the upper surface 507a of the upper layer portion 507 to form a Schottky barrier, and then a surface electrode metal film 511b is further formed to connect the Schottky metal film 511a and the conductive body 510. Furthermore, a back electrode metal film 512 is formed.

### (Semiconductor Device)

The semiconductor device 500 shown in FIG. 40 that can be produced by the above production method, for example, includes: the semiconductor substrate 501 that has a first conductivity type at a relatively high concentration; the first semiconductor layers 502, 507 that are deposited on the surface of the semiconductor substrate 501 and have the first conductivity type at a relatively low concentration; the second semiconductor layer 504P of the second conductivity type deposited on a bottom of a recess 513 of the first semiconductor layers 502, 507 by crystal growth using epitaxial growth; the trench 508 having a lateral surface constituted by the upper layer portion 507 of the first semiconductor layer and a bottom surface entirely constituted by the second semiconductor layer 504P; the insulating film 509a that covers the bottom surface and the lateral surface of the trench 508; the conductive body 510 that fills the inside of the trench 508 covered by the insulating film 509a; and the Schottky metal film 511a that electrically connects to the conductive body 510 and forms a Schottky barrier with the upper surface 507a of the upper layer portion 507 of the first semiconductor layer.

The second semiconductor layer 504P is arranged under the trench 508 and is within the region of the trench 508 in a plan view of the semiconductor substrate 501.

The region in the semiconductor layer deposited on the semiconductor substrate 501 except the region of the trench 508 in the plan view of the semiconductor substrate 501 is occupied by the first conductivity type (N-type) region. Therefore, it is possible to ensure a large conductive region for forward current under a Schottky junction.

The semiconductor device 500 can be applied to SBDs (Schottky diodes), MOSFETs (metal-oxide-semiconductor field-effect transistors), IGBTs (Insulated Gate Bipolar Transistors), and the like.

When the semiconductor device 500 constitutes a MOSFET, the P-body, gate, and the like are formed in the center portion, and the surface electrode metal film 511b serves as a source electrode and the back electrode metal film 512 serves as a drain electrode. When the semiconductor device 500 constitutes an IGBT, further, a p-type high-concentration substrate is applied as the semiconductor substrate 501, the surface electrode metal film 511b serves as an emitter electrode, and the back electrode metal film 512 serves as a collector electrode.

### Sixth Embodiment

Next, a production method for a semiconductor device according to a sixth embodiment and the semiconductor device will be described.

This embodiment will be described as a semiconductor device based on the semiconductor device 100 of the first embodiment or the semiconductor device 500 of the fifth embodiment above.

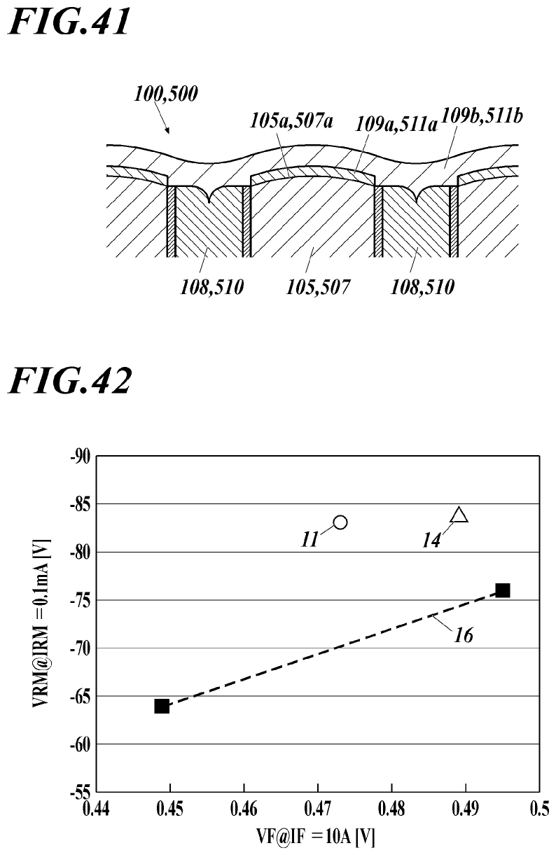

As shown in FIG. 41, the upper surfaces 105a and 507a of the upper layer portions 105 and 507 of the first semiconductor layer are formed in a convex shape, and the other features are as described in the above first or fifth embodiment.

The upper surfaces 105a, 507a protrude so that the tops are in the middle portion away from the conductive bodies 108, 510 on both sides. This structure allows the upper surfaces 105a, 507a to have larger areas and, therefore, larger Schottky junction surfaces, which are surfaces joined with the Schottky metal films 109a, 511a, and enables a larger forward current to flow. Therefore, it is possible to achieve forward characteristics with low on-resistance.

Such convex upper surfaces 105a, 507a can be configured by the production method described in the above first or fifth embodiment.

The upper layer portion 105 of the above first embodiment is deposited by the epitaxial growth method using the etching mask pattern 104 as a mask. Therefore, the amount of deposition is maximum in the middle away from the edge of the etching mask pattern 104, and the above convex upper surface 105a is formed.

The upper layer portion 507 of the above fifth embodiment is deposited by the epitaxial growth method using the nitride film 506 as a mask. Therefore, the amount of deposition is maximum in the middle away from the edge of the nitride film 506, and the above convex upper surface 507a is formed.

After that, without flattening the convex upper surfaces 105a, 507a, Schottky metal films 109a, 511a are vapor-deposited.

In this way, a Schottky junction can be obtained formed on the convex upper surfaces 105a, 507a.

### Effects

According to the above-described embodiments, the second semiconductor layer of the second conductivity type arranged under the trench relaxes the electric field when a reverse voltage is applied so as to improve the voltage resistance. Furthermore, it is possible to ensure the conductive region for forward current under a Schottky junction so as to suppress the increase in on-resistance.

Furthermore, a second semiconductor layer of the second conductivity type can be precisely formed in a desired range at the bottom of the trench using epitaxial technology without using an ion implantation method. Therefore, semiconductor materials for which ion implantation technology has not been sufficiently established, such as GaN (gallium nitride), can be selected as the semiconductor substrate 301, first semiconductor layers 102, 105, and second semiconductor layer 103. The semiconductor substrate 301, the first semiconductor layers 102, 105, and the second semiconductor layer 103 may be SiC (silicon carbide), diamond, Ga₂O₃ (gallium oxide), or AlN (aluminum nitride).

When epitaxial technology is used, the impurity profile can be made steeper than when ion implantation is used. Therefore, the second conductive type region is less likely to spread to the conductive region under the Schottky junction, and thus the increase in on-resistance can be suppressed.

According to the first or fifth embodiment, the shape of the trench can be configured without etching process. Therefore, post-treatment of a damaged etching surface becomes unnecessary.

According to the first or fifth embodiment, since the lower layer portion and the upper layer portion of the first semiconductor layer are stacked in separate processes, the doping concentration can be different between the lower layer portion and the upper layer portion of the first semiconductor layer. This can be expected to improve performance. (For example, by increasing the doping concentration in the lower layer portion compared to the upper layer portion, the on-resistance is reduced.)

### [Comparison of Characteristics]

FIG. 42 shows VF-VRM characteristics for the examples of comparison and the present invention. VF is a forward voltage when the forward current IF=10 [A]. VRM is the voltage resistance and is a reverse voltage when the reverse leakage current IRM=0.1 [mA].

A point 11 in the graph of FIG. 42 indicates the characteristics of the SBD of an example of the present invention according to the above first embodiment.

A point 14 in the graph of FIG. 42 indicates the characteristics of the SBD of a comparative example having a P-type region 103P protruding outward from the trench 106. The other conditions were common to those of the SBD of the example of the present invention (point 11).

A line 16 in the graph of FIG. 42 indicates the characteristics of the SBD of a comparative example having no P-type region 103P. The other conditions were common to those of the SBD of the example of the present invention (point 11). The line 16 indicates that, as the N-type impurity concentration in the semiconductor layer 102, 105 is decreased, VF and VRM tend to increase linearly.

Among the SBDs of comparative examples in which the P-type region 103P protrudes outward from the trench 106, the SBD indicated by point 14 had an improved voltage resistance VRM than a SBD of a comparative example having no P-type region 103P. However, the forward voltage VF increased in turn.

In the SBD of comparative examples having the P-type region 103P protruding outward from the trench 106, the forward voltage VF increases as the voltage resistance VRM is improved. This is because the improvement of voltage resistance is achieved, but is accompanied by an increase in on-resistance.

In contrast, in the SBD of the example of the present invention (point 11), the voltage resistance was improved while suppressing the increase in on-resistance. Thus, compared to the comparative examples, it was possible to achieve lower VF and higher voltage resistance VRM.

The embodiments of the present disclosure have been described above, but these embodiments are shown as examples and can be implemented in various other forms. Omission, replacement, or modification of components may be made as long as they do not depart from the gist of the invention.

### INDUSTRIAL APPLICABILITY

The present disclosure can be used for a semiconductor device and a production method for the semiconductor device.

### REFERENCE SIGNS LIST

100 Semiconductor Device
101 Semiconductor substrate
102,105 Semiconductor Layer (N-type)
103P Second Semiconductor Layer (P-type)
106 Trench
107a Insulating Film (Thermal Oxide Film)
108 Conductive Body
109a Schottky Metal Film
109b Surface Electrode Metal Film
110 Back Electrode Metal Film
111 Recess

1. A semiconductor device comprising:
a semiconductor substrate;
a first semiconductor layer of a first conductivity type that is deposited on a surface of the semiconductor substrate;
a second semiconductor layer of a second conductivity type that is deposited by crystal growth using epitaxial growth on a bottom of a recess of the first semiconductor layer;
a trench that comprises a lateral surface constituted by the first semiconductor layer and a bottom surface at least partly constituted by the second semiconductor layer;
an insulating film that covers the bottom surface and the lateral surface of the trench;
a conductive body that is inside the trench that is covered by the insulating film; and
a metal film that is electrically connected to the conductive body and forms a Schottky barrier with a surface of the first semiconductor layer,
wherein the second semiconductor layer constitutes all or a middle portion of the bottom surface of the trench and is within a region of the trench in a plan view of the semiconductor substrate.

2. The semiconductor device according to claim 1,
wherein the second semiconductor layer constitutes the middle portion of the bottom surface of the trench and is within the region of the trench without being in contact with an outer edge of the region of the trench in the plan view of the semiconductor substrate, and
the first semiconductor layer constitutes an outer edge portion of the bottom surface of the trench excluding the middle portion.

3. The semiconductor device according to claim 2,
wherein the outer edge portion constituted by the first semiconductor layer and the middle portion constituted by the second semiconductor layer are located at a substantially same depth.

4. The semiconductor device according to claim 2,
wherein the middle portion constituted by the second semiconductor layer is protruded with respect to the outer edge portion constituted by the first semiconductor layer.

5. The semiconductor device according to claim 1,
wherein a first conductive type region occupies a region in a semiconductor layer except a region of the trench in the plan view of the semiconductor substrate, the semiconductor layer being deposited on the semiconductor substrate.

6. The semiconductor device according to claim 1,
wherein the semiconductor substrate, the first semiconductor layer, and the second semiconductor layer include GaN.

7. The semiconductor device according to claim 1,
wherein the semiconductor substrate, the first semiconductor layer, and the second semiconductor layer include one of SiC, diamond, Ga₂O₃, and AlN.

8. A production method for a semiconductor device, comprising the semiconductor device including:
depositing a first semiconductor layer of a first conductivity type on a surface of a semiconductor substrate;
depositing a second semiconductor layer of a second conductivity type on a bottom of a recess of the first semiconductor layer;
forming a trench that has a lateral surface constituted by the first semiconductor layer and a bottom surface at least partly constituted by the second semiconductor layer;
covering the bottom surface and the lateral surface of the trench with an insulating film;
filling a conductive body inside the trench that is covered by the insulating film; and
connecting a metal film to the conductive body and forms a Schottky barrier with a surface of the first semiconductor layer;
depositing the second semiconductor layer including an impurity of a second conductivity type by epitaxial growth on the first semiconductor layer.

9. The production method for the semiconductor device according to claim 8,
wherein, in the depositing of the second semiconductor layer, the second semiconductor layer is deposited on a lower layer portion of the first semiconductor layer deposited on the semiconductor substrate, and
after the depositing of the second semiconductor layer, a part of a semiconductor layer deposited in the depositing of the second semiconductor layer remaining after selective etching is the second semiconductor layer, and the trench is constituted by depositing an upper layer portion of the first semiconductor layer that adjoins a perimeter of the second semiconductor layer, the first semiconductor layer being thicker than the second semiconductor layer.

10. The production method for the semiconductor device according to claim 8, further comprising:
forming a recess in the first semiconductor layer by etching of the first semiconductor layer using a mask before the depositing of the second semiconductor layer, the mask being an insulator mask pattern that is formed on a surface of the first semiconductor layer and being open at a region where the trench is to be formed, and
forming a mask to form an insulator mask pattern that covers a surface of the first semiconductor layer around the recess, an outer edge portion of a bottom surface of the recess, and a lateral surface of the recess, and exposes a middle portion of the bottom surface,
wherein, in the depositing of the second semiconductor layer, the second semiconductor layer is deposited on the first semiconductor layer that is exposed at the middle portion of the bottom surface using an insulator mask pattern formed in the forming of the mask as a mask.

11. The production method for the semiconductor device according to claim 10, further comprising:
forming a small recess in the first semiconductor layer at the middle portion of the bottom surface of the recess by etching of the first semiconductor layer exposed at a middle portion of the bottom surface using a mask after the forming of the mask and before the depositing of the second semiconductor layer, the mask being an insulator mask pattern that is formed in the forming of the mask;
wherein, in the depositing of the second semiconductor layer, the second semiconductor layer is deposited in the small recess using a mask that is an insulator mask pattern formed in the mask formation.

12. The production method for the semiconductor device according to claim 10,
wherein the forming of the mask includes:
forming an insulator layer that is deposited on the insulator mask pattern formed in the forming of the recess and that covers the bottom surface and the lateral surface of the recess; and
anisotropic etching of the insulator layer by which a middle portion of the bottom surface of the recess is exposed and an insulator remains, the insulator being a part of the insulator layer and adhering to an outer edge portion of the bottom surface and the lateral surface of the recess.

13. The production method for the semiconductor device according to claim 8, wherein,
before the depositing of the second semiconductor layer, a mask pattern is formed on a surface of a lower layer portion of the first semiconductor layer deposited on the semiconductor substrate, the mask pattern being open at a region where the trench is to be formed,
in the depositing of the second semiconductor layer, the second semiconductor layer that is thinner than the mask pattern is deposited on the lower layer portion in the region where the trench is to be formed using the mask pattern as a mask, and a resulting gap is filled with a nitride film, and
the trench is constituted by removing the mask pattern, depositing an upper layer portion of the first semiconductor layer on the lower layer portion from which the mask pattern is removed, and removing the nitride film, the upper layer portion being thicker than the second semiconductor layer.

14. The production method for the semiconductor device according to claim 8,
wherein the semiconductor substrate, the first semiconductor layer, and the second semiconductor layer include GaN.

15. The production method for the semiconductor device according to claim 8,
wherein the semiconductor substrate, the first semiconductor layer, and the second semiconductor layer include one of SiC, diamond, Ga₂O₃, and AlN.
